(19) United States
(12) Patent Application Publication
(10) Pub. No.: US 2009/0302468 A1
(43) Pub. Date: Dec. 10, 2009

(54) Printed circuit board comprising semiconductor chip and method of manufacturing the same

(75) Inventors: Jong Hwan Baek, Seoul (KR); Sung Yi, Gyunggi-do (KR); Young Do Kweon, Gyunggi-do (KR); Jong Yun Lee, Incheon (KR); Hyung Jin Jeon, Gyunggi-do (KR); Joon Seok Kang, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/232,252

(22) Filed: Sep. 12, 2008

(30) Foreign Application Priority Data
Jun. 5, 2008 (KR) 10-2008-0053041

(51) Int. Cl. H01L 23/488; H01L 21/56

(52) U.S. Cl. 257/738; 438/127; 257/E23.023; 257/E21.502

(57) ABSTRACT

Disclosed is a printed circuit board including a semiconductor chip, which includes a semiconductor chip having a connection pad, which is exposed, on the upper surface thereof, a first solder ball formed on the connection pad and having a first melting point, a printed circuit board having an external connection terminal formed at the outermost circuit layer thereof, and a second solder ball formed on the external connection terminal, connected to the first solder ball, and having a second melting point higher than the first melting point. In the printed circuit board including a semiconductor chip, the distance between the printed circuit board and the semiconductor chip is increased, thus realizing high resistance to flexure due to the difference in thermal expansion coefficient between the printed circuit board and the semiconductor chip.

### CROSS REFERENCE TO RELATED APPLICATION

This application claims the benefit of Korean Patent Application No. 10-2008-0053041, filed Jun. 5, 2008, entitled “A printed circuit board comprising a semiconductor chip and a method for manufacturing the same”, which is hereby incorporated by reference in its entirety into this application.

### BACKGROUND OF THE INVENTION

1. Field of the Invention

The present invention relates to a printed circuit board (PCB) including a semiconductor chip and a method of manufacturing the same, and more particularly, to a PCB, which has a second solder ball having a melting point higher than that of a first solder ball formed on a semiconductor chip.

2. Description of the Related Art

In the semiconductor industry, semiconductor technology is mainly aimed towards a reduction in the size of a semiconductor device. In the field of the semiconductor device package, as the demand of small computers and portable electronics has rapidly increased, the semiconductor device package, such as fine-pitch ball grid array (FBGA) package having a small size and realizing a plurality of pins, has been being developed.

Typically, the mounting of a semiconductor device on a PCB using a solder ball is conducted in a manner such that the solder ball is formed on the connection pad of the semiconductor device and the same solder ball is connected to the external connection terminal of the PCB, thus mounting the semiconductor device on the PCB. However, this case is problematic because flexure occurs after or during the process of mounting the semiconductor device on the PCB, attributable to the difference in thermal expansion coefficient between the semiconductor device and the PCB. As such, when the distance between the PCB and the semiconductor device is shorter, stress is concentrated on the solder ball, thereby incurring a phenomenon in which the solder ball becomes broken or separated from the connection pad. Accordingly, there has been proposed a structure in which a copper pillar is formed on the semiconductor chip or a solder ball is formed in a plurality of layers, to increase the distance between the PCB and the semiconductor device so that the stress concentrated on the solder ball is lessened.

FIGS. 1A and 1B show the process of mounting a semiconductor chip having a double solder ball structure on a PCB according to a conventional technique.

With reference to FIG. 1A, a solder ball 5 having a double ball structure is formed on a connection pad 3, which is formed above a semiconductor chip 1. As shown in FIG. 1B, the solder ball 5 having a double ball structure is connected to an external connection terminal 7, which is formed on a PCB 9, through a reflow process. In this way, in the case where the solder ball 5 having a double ball structure is used, the distance between the PCB and the semiconductor device may be increased more than when using a solder ball having a single ball structure, thus reducing the stress concentrated on the solder ball, consequently ensuring the reliability of a completed semiconductor apparatus.

However, because the process of forming the solder ball 5 on the semiconductor device 1 is conducted at the wafer level which is relatively complicated, the process of forming the double ball structure on the semiconductor device makes the wafer-level process more complicated.

### SUMMARY OF THE INVENTION

Therefore, the present invention has been made keeping in mind the above problems encountered in the related art, and provides a PCB and a method of manufacturing the same, by which the wafer-level semiconductor manufacturing process is simplified, and the distance between a semiconductor chip and a PCB is increased, thus realizing a highly reliable PCB.

According to the present invention, a PCB comprising a semiconductor chip may comprise a semiconductor chip having a connection pad, which is exposed, on the upper surface thereof; a first solder ball formed on the connection pad and having a first melting point; a PCB having an external connection terminal formed at the outermost circuit layer thereof; and a second solder ball formed on the external connection terminal, connected to the first solder ball, and having a second melting point higher than the first melting point.

According to a preferred feature of the present invention, the PCB may further comprise a resin sealing portion, which sealingly covers the upper surface of the semiconductor chip and has an opening for exposing the first solder ball.

According to another preferred feature of the present invention, the second solder ball may have a spherical or hemispherical shape.

According to a further preferred feature of the present invention, the difference between the first melting point and the second melting point may be greater than 15° C.

In addition, according to the present invention, a method of manufacturing a PCB comprising a semiconductor chip may comprise (A) forming a first solder ball having a first melting point on a connection pad, which is exposed, on the upper surface of a semiconductor chip; (B) forming a second solder ball having a second melting point higher than the first melting point on an external connection terminal formed at the outermost layer of a PCB; and (C) connecting the first solder ball to the second solder ball at a temperature between the first melting point and the second melting point.

According to a preferred feature of the present invention, the second solder ball may have a spherical or hemispherical shape.

According to another preferred feature of the present invention, the difference between the first melting point and the second melting point may be greater than 15° C.

According to a further preferred feature of the present invention, forming the first solder ball may comprise (i) disposing a first mask having a first solder ball-forming opening for exposing the connection pad on the semiconductor chip; (ii) filling the opening of the first mask with a first solder; and (iii) removing the first mask and performing a reflow process, thus forming the first solder ball.

According to still a further preferred feature of the present invention, forming the second solder ball may comprise (i) disposing a second mask having a second solder ball-forming opening for exposing the external connection terminal on the outermost layer of the PCB; (ii) filling the opening of the second mask with a second solder; and (iii) removing the second mask and performing a reflow process, thus forming the second solder ball.

According to yet another preferred feature of the present invention, connecting the first solder ball to the second solder ball may comprise (i) applying a flux on exposed surfaces of the first solder ball and the second solder ball; and (ii) performing a reflow process at a temperature between the first melting point and the second melting point, thus connecting the first solder ball to the second solder ball.

According to still another preferred feature of the present invention, the method may further comprise forming a resin sealing portion which sealingly covers the upper surface of the semiconductor chip and has an opening for exposing the first solder ball, after forming the first solder ball.

The features and advantages of the present invention will be more clearly understood from the following detailed description taken in conjunction with the accompanying drawings.

Further, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

FIGS. 1A and 1B are schematic views showing a process of mounting a semiconductor chip including a solder ball having a double ball structure on a PCB according to a conventional technique;

FIG. 2 is a cross-sectional view showing a PCB including a semiconductor chip, according to the present invention; and

FIGS. 3 to 11 are schematic views sequentially showing a process of manufacturing the PCB including a semiconductor chip according to the present invention.

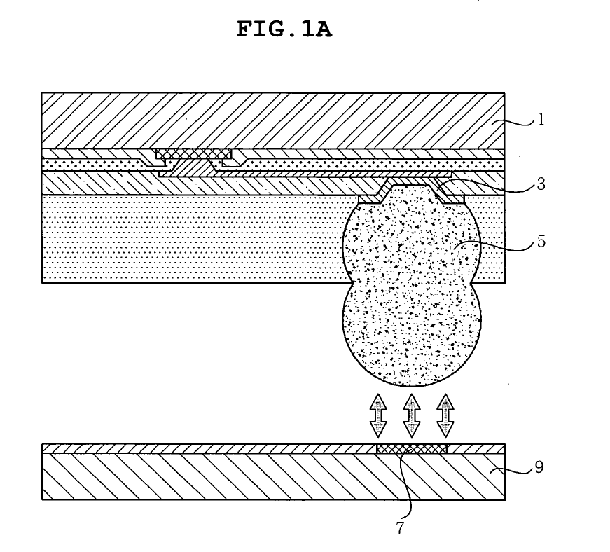

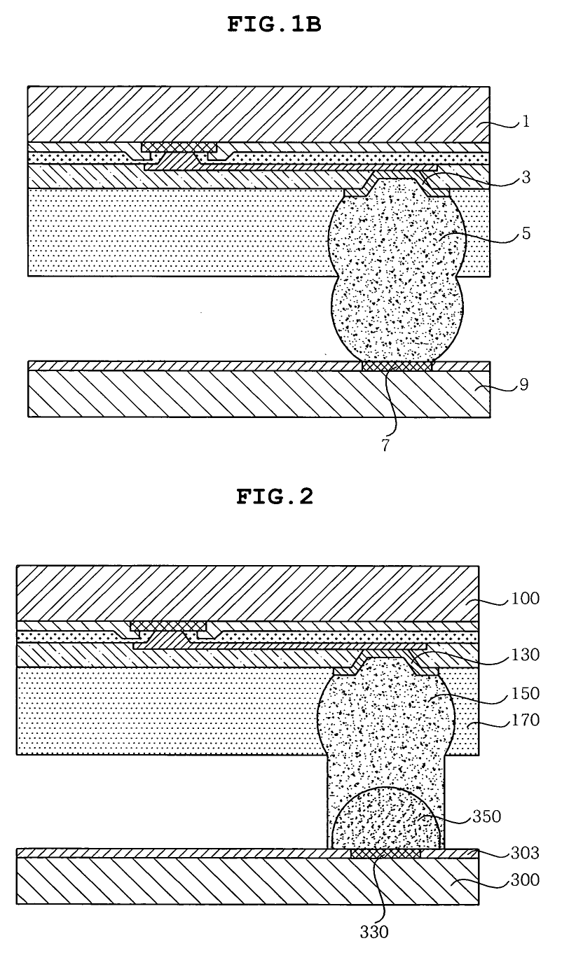

### DESCRIPTION OF THE PREFERRED EMBODIMENTS

Hereinafter, a detailed description will be given of a PCB 300 including a semiconductor chip 100 and a method of manufacturing the same according to preferred embodiments of the present invention, with reference to the appended drawings. Throughout the drawings, like reference numerals refer to like elements, and redundant descriptions are omitted. In the description, the terms “first”, “second” and so on are used to distinguish one element from another element, but are not to be construed to limit the elements.

FIG. 2 is a cross-sectional view illustrating the PCB 300 including the semiconductor chip 100 according to the present invention.

As illustrated in FIG. 2, the PCB 300 according to the present invention includes the semiconductor chip 100 having a connection pad 130, which is exposed, on the upper surface thereof, a first ball 150 formed on the connection pad 130 and having a first melting point, a PCB 300 having an external connection terminal 330 formed at an outermost circuit layer thereof, and a second solder ball 350 formed on the external connection terminal 330, connected to the first solder ball 150, and having a second melting point higher than the first melting point.

The semiconductor chip 100 has a structure in which a bonding pad 103 electrically connected to an integrated circuit (not shown) is formed on the upper surface of a chip body made of silicon material in which the integrated circuit is embedded, and a passivation layer is formed on the upper surface of the chip body to expose the bonding pad 103.

The passivation layer 101 is a thin insulating film resulting from lamination of a first insulating film (not shown) formed of silicon dioxide (SiO₂), a second insulating film (not shown), and a third insulating film (not shown) formed of silicon nitride (SiN), thereby realizing high heat resistance and high electrical insulating properties. The surface of the passivation layer 101 functions as the surface of the semiconductor chip 100.

The bonding pad 103 is formed of metal, such as aluminum.

A first insulating layer 105 is responsible for protecting the active surface or passivation layer 101 of the semiconductor chip 100 from heat or mechanical stress that occurs in the event of reproduction treatment, and includes a first opening to expose the bonding pad 103 from the upper surface of the semiconductor chip 100. The first insulating layer 105 is formed of, for example, polyimide or epoxy.

A rewiring layer 107, acting to guide a wiring from the bonding pad 103 of the semiconductor chip 100 to the connection pad 130, which is larger than the bonding pad and is located at a position different from the position of the bonding pad, is extended on the first insulating layer 105 while being connected to the bonding pad 103.

In the present invention, one end of the rewiring layer 107 is connected to the bonding pad 103, and the other end thereof is connected to the connection pad 130 which is linked to the first solder ball 150 or external connection terminal 330. The rewiring layer 107 is formed of conductive metal, for example, aluminum (Al), copper (Cu), nickel (Ni), gold (Au), etc. In the present invention, the formation of the connection pad 130 on the rewiring layer 107 is illustrative, but the end of the rewiring layer 107 may function as the connection pad 130 without additional use of a connection pad 130, or the connection pad 130 may be provided in the form of a Cu pillar.

A second insulating layer 109, acting to protect the rewiring layer 107, is formed on the first insulating layer 105, and is provided with a second opening (not shown) for exposing the connection pad 130. The second insulating layer 109 is formed of, for example, epoxy.

The first solder ball 150 plays a role as an external connection terminal for connecting the semiconductor chip 100 connected with the rewiring layer 107 to an external system, and is formed on the connection pad 130 of the rewiring layer 107. The material for the first solder ball 150 is described below along with the material for the second solder ball 350.

A resin sealing portion 170 is responsible for protecting the upper layer structure formed on the semiconductor chip 100 and supporting the first solder ball 150, and is formed to sealingly cover the second insulating layer 109 including the first solder ball 150. The resin sealing portion 170 is formed of, for example, an epoxy molding compound.

The PCB 300 is used to mount electronic parts and for wiring, and is typically manufactured by etching a metal layer along a wiring pattern (removing portions other than circuit lines through etching), thus forming desired circuits. Further, the external connection terminal 330 is provided on the outermost layer of the PCB 300 to mediate the connection with an electronic component such as a semiconductor chip 100.

As such, the PCB 300 according to the present invention may be a single-sided PCB in which a wiring is formed on only one surface of an insulating substrate, a double-sided PCB in which a wiring is formed on both surfaces of an insulating substrate, and a multi-layered board (MLB) including multiple wiring layers. As the PCB 300, any one known in the art may be used, and thus the detailed description for the construction of the PCB is omitted.

The PCB 300 according to the present invention includes the second solder ball 350 formed on the external connection terminal 330, which is provided on the outermost layer thereof. The second solder ball 350 is electrically and physically connected with the first solder ball 150 of the semiconductor chip 100 so that the semiconductor chip 100 is mounted on the PCB 300. The second solder ball 350 is provided to maintain the distance between the PCB 300 and the semiconductor chip 100, which is mounted on the PCB 300, in a predetermined distance or more. In an exemplary embodiment, the second solder ball 350 has a spherical or hemispherical shape. FIG. 2 illustrates the second solder ball 350 having a hemispherical shape.

In the present invention, each of the second solder ball 350 and the first solder ball 150 formed on the connection pad 130 of the semiconductor chip 100 may be formed using any solder material selected from among tin/lead (Sn/Pb), tin/silver/copper (Sn/Ag/Cu), tin/silver (Sn/Ag), tin/copper (Sn/Cu), tin/bismuth (Sn/Bi), tin/zinc/bismuth (Sn/Zn/Bi), tin/silver/bismuth (Sn/Ag/Bi), tin/silver/zinc (Sn/Ag/Zn), indium/tin (In/Sn), indium/silver (In/Ag), tin/lead/silver (Sn/Pb/Ag), indium/lead (In/Pb), tin (Sn), tin/lead/bismuth (Sn/Pb/Bi), and tin/lead/bismuth/silver (Sn/Pb/Bi/Ag).

Depending on the type of selected solder material, the first solder ball 150 and the second solder ball 350 may have different melting points from each other. Table I below shows the properties of eight solder materials, which are illustratively selected.

TABLE 1
Melting Point & Specific Gravity of Solder Materials

| Type | Composition | Melting Point (° C.) | Specific Gravity |
|---|---|---|---|
| Tin/Lead | Sn/37Pb | 183 | 8.4 |
| | Sn/36Pb/2Ag | 179~191 | 8.4 |
| | Sn/90Pb | 275~302 | 10.7 |
| | Sn/10Pb | 183~213 | 7.55 |
| Lead-free | Sn/2.5Ag/0.5Cu | 217~219 | 7.4 |
| | Sn/4Ag/0.5Cu | 217~219 | 7.4 |
| | Sn/3.5Ag | 219~223 | 7.36 |
| | Sn/3Ag/0.5Cu | 217~219 | 7.4 |

In the present invention, the first solder ball 150 and the second solder ball 350 are formed of different materials. Specifically, the second solder ball 350 is formed of material having a melting point higher than that of the material selected for the first solder ball 150. The melting point of the first solder ball 150 is referred to as a first melting point, and the melting point of the second solder ball 350 is referred to as a second melting point. In a preferred embodiment, the difference between the first melting point and the second melting point is set to be larger than 15° C.

In an exemplary embodiment, the first solder ball 150 is formed of tin/lead (Sn/Pb) having a composition ratio of 63/37 and a melting point of 183° C., and the second solder ball 350 is formed of tin/silver/copper (Sn/Ag/Cu) having a composition ratio of 96.5/3/0.5 and a melting point of 217° C.

As shown in FIG. 2, the second solder ball 350 still has a hemispherical shape even after being subjected to a connection process with the first solder ball 150 which is described later. This indicates that the second solder ball 350 is not melted during the connection process and the height thereof before the connection process is maintained without change even after the completion of the connection process, thus contributing to increasing the distance between the PCB 300 and the semiconductor chip 100. In this way, when the distance between the PCB 300 and the semiconductor chip 100 is increased, resistance to flexure due to the difference in the thermal expansion coefficient between the PCB 300 and the semiconductor chip 100 is increased.

As well, the original shape of the second solder ball 350 is maintained, and thus, a solder bridging phenomenon between adjacent solder balls during the process of mounting the semiconductor chip 100 may be prevented.

Below, the method of manufacturing the PCB 300 including the semiconductor chip 100 according to the present invention is described.

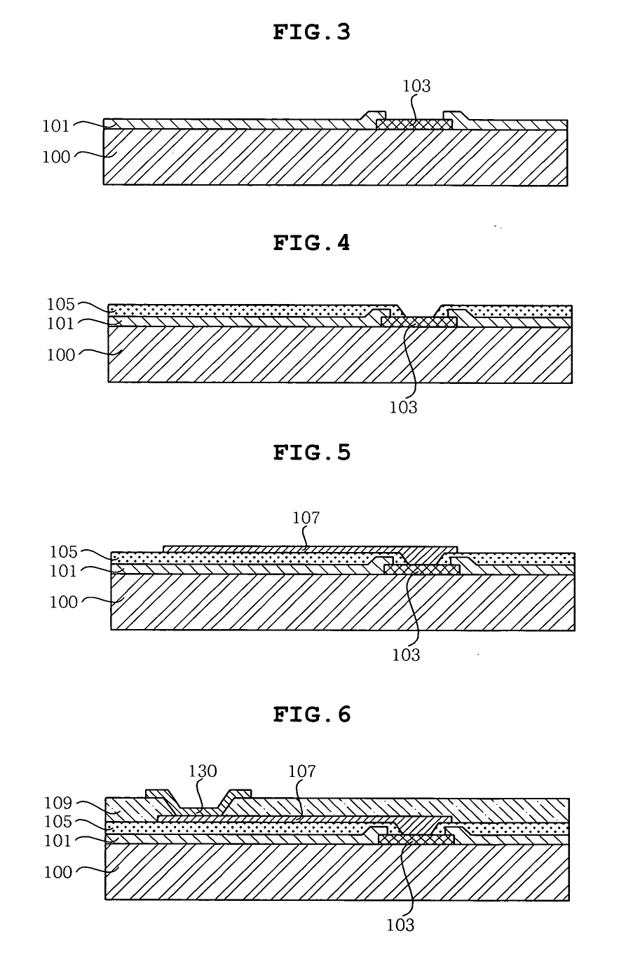

First, the process of manufacturing the semiconductor chip 100, which is to be mounted on the PCB 300, is described. FIGS. 3 to 8 sequentially show the process of manufacturing the semiconductor chip 100, which is to be mounted on the PCB 300 having a high-melting-point solder ball. In the present invention, the manufacturing process is described with respect to each semiconductor chip 100, but it is noted that the manufacturing process may be conducted at the wafer level including a plurality of semiconductor chips 100.

As shown in FIG. 3, a semiconductor chip 100 is provided, and a first insulating layer 105 having an opening for exposing a bonding pad 103 is formed on the semiconductor chip 100, as shown in FIG. 4.

As such, the semiconductor chip 100 has a structure in which the bonding pad 103, electrically connected with an integrated circuit (not shown), is formed on the upper surface of a chip body made of silicon material including the integrated circuit, and a passivation layer 101 is formed on the upper surface of the chip body to expose the bonding pad 103. The formation of the bonding pad 103 and the passivation layer 101 is conducted through a fabrication (FAB) process.

The first insulating layer 105 has the first opening for exposing the bonding pad 103 of the semiconductor chip 100 and is formed on the passivation layer 101.

The first opening may be formed by forming a photosensitive resin layer on the first insulating layer 105 and patterning the photosensitive resin layer to expose the bonding pad 103 through photolithography.

Next, as shown in FIG. 5, a rewiring layer 107 is formed. The rewiring layer 107 is extended on the first insulating layer 105 while being connected to the bonding pad 103.

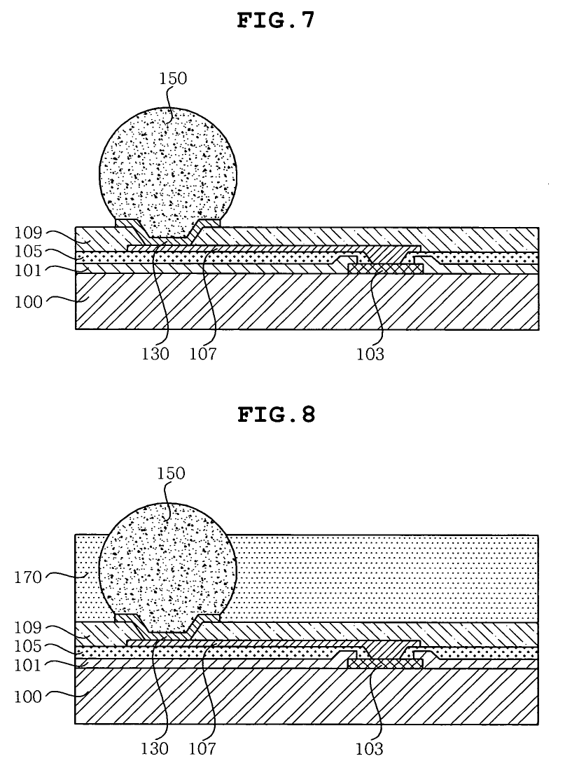

Next, as shown in FIG. 6, a second insulating layer 109 and a connection pad 130 are formed. The second insulating layer 109 is formed on the first insulating layer 105 and the rewiring layer 107, and is provided with an opening (not shown: a portion having no second insulating layer 109 on the connection pad 130) for exposing one end of the rewiring layer 107. In the opening of the second insulating layer 109, the connection pad 130 which is connected to one end of the rewiring layer 107 is formed. In the present invention, the additional formation of the connection pad 130 on the rewiring layer 107 is illustratively shown, but the end of the rewiring layer 107 may function as the connection pad 130 without the additional use of a connection pad 130. The connection pad 130 may be provided in the form of a Cu-pillar.

Next, as shown in FIG. 7, a first solder ball 150 for connecting the semiconductor chip 100 to an external system is formed on the connection pad 130.

As mentioned above, the first solder ball 150 may be formed of any solder material selected from among tin/lead (Sn/Pb), tin/silver/copper (Sn/Ag/Cu), tin/silver (Sn/Ag), tin/copper (Sn/Cu), tin/bismuth (Sn/Bi), tin/zinc/bismuth (Sn/Zn/Bi), tin/silver/bismuth (Sn/Ag/Bi), tin/silver/zinc (Sn/Ag/Zn), indium/tin (In/Sn), indium/silver (In/Ag), tin/lead/silver (Sn/Pb/Ag), indium/lead (In/Pb), tin (Sn), tin/lead/bismuth (Sn/Pb/Bi), and tin/lead/bismuth/silver (Sn/Pb/Bi/Ag).

The first solder ball 150 may be formed through a known process in the art. Below, the process of forming the first solder ball 150 is briefly described.

A flux is applied on the connection pad 130 of the semiconductor chip 100, and a mask for forming the first solder ball 150 is disposed thereon. The mask for forming the solder ball includes a plurality of first solder supply openings able to supply the first solder on the flux. Then, the first solder is supplied into the supply openings using a squeegee, and the first solder is temporarily held on the viscous flux. Then, the mask is removed, and a reflow process is conducted, thus forming the first solder ball 150 on the connection pad 130.

Next, as shown in FIG. 8, a resin sealing portion 170, which is patterned, is formed so as to sealingly cover the first solder ball 150 and the second insulating layer 109. The resin sealing portion 170 is formed of an epoxy molding compound.

After the resin sealing portion 170 is formed, the process of removing the resin sealing portion 179 from the upper end area of the first solder ball 150 so that the first solder ball 150 functions as the external connection terminal 330 may be performed. This removal process is carried out through plasma surface treatment or CMP (Chemical Mechanical Polishing).

Thereafter, a second solder ball 350 is formed on the PCB 300 on which the semiconductor chip 100 thus obtained is to be mounted. For convenience of the description, the process of manufacturing the semiconductor chip 100 is first described, but it will be apparently understood that the process of forming the first solder ball on the PCB 300 may be previously conducted separately from the process of manufacturing the semiconductor chip 100 or may be conducted at the same time as the process of manufacturing the semiconductor chip 100.

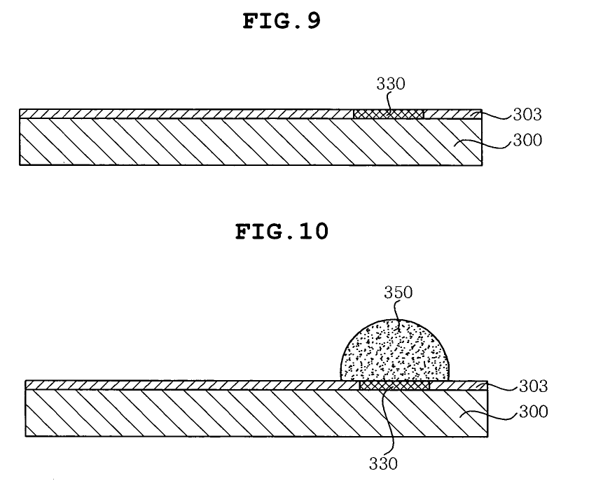

FIGS. 9 and 10 schematically show the process of forming the second solder ball 350 on the PCB 300, according to the present invention.

As shown in FIG. 9, the PCB 300 having the external connection terminal 330 formed at the outermost layer thereof is provided. The PCB 300 may be a single-sided PCB 300, a double-sided PCB 300, or an MLB 300, any of which is provided with the external connection terminal 330 on which the semiconductor chip 100 is to be mounted.

At the outermost layer of the PCB 300, a solder resist layer 303 may be formed as known in the art. In this case, an opening is formed in the solder resist layer 303 to expose the external connection terminal 330.

Next, as shown in FIG. 10, the second solder ball 350 is formed on the external connection terminal 330 of the PCB 300.

The second solder ball 350 may be formed of any solder material selected from among tin/lead (Sn/Pb), tin/silver/copper (Sn/Ag/Cu), tin/silver (Sn/Ag), tin/copper (Sn/Cu), tin/bismuth (Sn/Bi), tin/zinc/bismuth (Sn/Zn/Bi), tin/silver/bismuth (Sn/Ag/Bi), tin/silver/zinc (Sn/Ag/Zn), indium/tin (In/Sn), indium/silver (In/Ag), tin/lead/silver (Sn/Pb/Ag), indium/lead (In/Pb), tin (Sn), tin/lead/bismuth (Sn/Pb/Bi), and tin/lead/bismuth/silver (Sn/Pb/Bi/Ag).

As such, the second solder ball 350 must be formed of material having a melting point higher than that of the material selected for the first solder ball 150. In a preferred embodiment, the material for the second solder ball 350 is selected such that the difference in melting point between the second solder ball 350 and the first solder ball 150 is greater than 15° C.

In the present invention, the process of forming the second solder ball 350 is very similar to the process of forming the first solder ball 150, and any other known method may be applied, and thus a detailed description thereof is omitted.

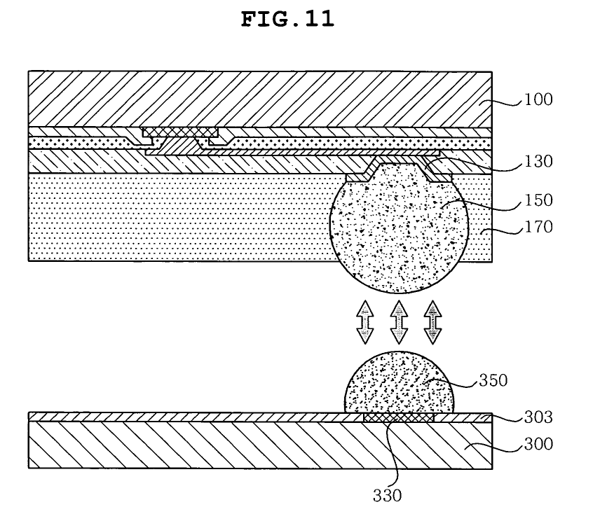

Next, as shown in FIG. 11, the semiconductor chip 100 is mounted on the PCB 300. The mounting of the semiconductor chip 100 is conducted through surface mounting technology for connecting the first solder ball 150 and the second solder ball 350.

The flux is applied on the connection pads of the first solder ball 150 and the second solder ball 350, and a reflow process is conducted, thus connecting the first solder ball 150 to the second solder ball 350. In this case, a reflow process is performed at a temperature higher than the melting point of the first solder ball 150 and lower than the melting point of the second solder ball 350. That is, during the reflow process, the first solder ball 150 is melted and is then connected to the second solder ball 350, and the second solder ball 350 is not melted, thus maintaining the original shape of the second solder ball 350.

In the exemplary embodiment, the first solder ball 150 is formed of tin/lead (Sn/Pb) having a composition ratio of 63/37 and a melting point of 183° C., and the second solder ball 350 is formed of tin/silver/copper (Sn/Ag/Cu) having a composition ratio of 96.5/3/0.5 and a melting point of 217° C. Further, the reflow process for connecting the first solder ball 150 and the second solder ball 350 is performed at 190˜210° C.

Through the above manufacturing process, the PCB 300 including the semiconductor chip 100, as shown in FIG. 2, may result.

As described hereinbefore, the present invention provides a PCB including a semiconductor chip and a method of manufacturing the same. In the PCB including the semiconductor chip according to the present invention, the distance between the PCB and the semiconductor chip is increased, thus realizing high resistance to flexure due to the difference in thermal expansion coefficient between the PCB and the semiconductor chip.

According to the present invention, a second solder ball is maintained in an original shape, thus preventing a solder bridging phenomenon between adjacent solder balls during the process of mounting the semiconductor chip on the PCB.

Although the preferred embodiments of the present invention have been disclosed for illustrative purposes, those skilled in the art will appreciate that various modifications, additions and substitutions are possible within the technical scope of the invention.

1. A printed circuit board comprising a semiconductor chip, comprising:
a semiconductor chip having a connection pad, which is exposed, on an upper surface thereof;
a first solder ball formed on the connection pad and having a first melting point;
a printed circuit board having an external connection terminal formed at an outermost circuit layer thereof; and
a second solder ball formed on the external connection terminal, connected to the first solder ball, and having a second melting point higher than the first melting point.

2. The printed circuit board as set forth in claim 1, further comprising a resin sealing portion, which sealingly covers an upper surface of the semiconductor chip and has an opening for exposing the first solder ball.

3. The printed circuit board as set forth in claim 1, wherein the second solder ball has a spherical or hemispherical shape.

4. The printed circuit board as set forth in claim 1, wherein a difference between the first melting point and the second melting point is greater than 15° C.

5. A method of manufacturing a printed circuit board comprising a semiconductor chip, comprising:
forming a first solder ball having a first melting point on a connection pad, which is exposed, on an upper surface of a semiconductor chip;
forming a second solder ball having a second melting point higher than the first melting point on an external connection terminal formed at an outermost layer of a printed circuit board; and
connecting the first solder ball to the second solder ball at a temperature between the first melting point and the second melting point.

6. The method as set forth in claim 5, wherein the second solder ball has a spherical or hemispherical shape.

7. The method as set forth in claim 5, wherein a difference between the first melting point and the second melting point is greater than 15° C.

8. The method as set forth in claim 5, wherein the forming the first solder ball comprises:
disposing a first mask having a first solder ball-forming opening for exposing the connection pad on the semiconductor chip;
filling the opening of the first mask with a first solder; and
removing the first mask and performing a reflow process, thus forming the first solder ball.

9. The method as set forth in claim 5, wherein the forming the second solder ball comprises:
disposing a second mask having a second solder ball-forming opening for exposing the external connection terminal on the outermost layer of the printed circuit board;
filling the opening of the second mask with a second solder; and
removing the second mask and performing a reflow process, thus forming the second solder ball.

10. The method as set forth in claim 5, wherein the connecting the first solder ball to the second solder ball comprises:
applying a flux on exposed surfaces of the first solder ball and the second solder ball; and
performing a reflow process at a temperature between the first melting point and the second melting point, thus connecting the first solder ball to the second solder ball.

11. The method as set forth in claim 5, further comprising forming a resin sealing portion which sealingly covers the upper surface of the semiconductor chip and has an opening for exposing the first solder ball, after forming the first solder ball.
